(19) United States
(12) Patent Application Publication
(10) Pub. No.: US 2006/0056473 A1
(43) Pub. Date: Mar. 16, 2006

(54) Semiconductor light emitting element and method for fabricating the same

(76) Inventors: Tatsuya Tanigawa, Osaka (JP); Toshikazu Onishi, Kyoto (JP); Tetsuzo Ueda, Osaka (JP)

Correspondence Address: MCDERMOTT WILL & EMERY LLP, 600 13TH STREET, N.W., WASHINGTON, DC, 20005-3096, US

(21) Appl. No.: 11/195,625

(22) Filed: Aug. 3, 2005

(30) Foreign Application Priority Data
Aug. 20, 2004 (JP) 2004-240485

(51) Int. Cl. H01S 5/00

(52) U.S. Cl. 372/43.01

(57) ABSTRACT

A surface emitting laser element includes a mesa structure of a semiconductor multilayer film formed to have a convex cross section. A first insulating film of an inorganic material is formed on a side surface of the mesa structure, and on the first insulating film, a resin layer is formed to fill a space surrounding the mesa structure. A second insulating film of an inorganic material is formed on the resin layer, and an upper contact electrode with an electrode opening exposing part of the top surface of the mesa structure is formed on the second insulating film and the mesa structure. With this construction, oxidation and alteration of the resin layer during fabrication of the element can be suppressed to bury the mesa structure with no gap created. Therefore, a semiconductor light-emitting element with high reliability can be provided.

### CROSS-REFERENCE TO RELATED APPLICATIONS

This application claims priority under 35 U.S.C. § 119 on patent applications No. 2004-240485 filed in Japan on Aug. 20, 2004, and No. 2005-160254 filed in Japan on May 31, 2005, the entire contents of which are hereby incorporated by reference.

### BACKGROUND OF THE INVENTION

(a) Fields of the Invention

The present invention relates to semiconductor light-emitting elements applicable to surface emitting semiconductor laser elements or the like, and to methods for fabricating such an element.

(b) Description of Related Art

In recent years, rapid proliferation of the Internet has pushed the amount of data transmission sharply, so that high-capacity data communications networks have been required.

Surface emitting laser elements (or vertical cavity surface emitting laser elements (VCSELs)) are characterized in that laser light can be emitted in a perpendicular direction to the principal surface of a substrate formed with the element and in that the element has a low threshold current and a high power conversion efficiency. In addition to this, the surface emitting laser elements have various advantages that: they can output circular outgoing light whose cross section perpendicular to the optical axis is circular; two-dimensional arrangement of them is facilitated; and inspection of them is carried out easily; other advantages. Moreover, the surface emitting laser elements are expected to be fabricated at low cost. Thus, in the future, the surface emitting laser elements are expected to obtain more increasing demand as light sources for high-capacity data communications.

In an optical communications system made by combining a surface emitting laser element with a plastic optical fiber (POF), the surface emitting laser element and the plastic optical fiber can both be fabricated at low cost, so that this system offers prospects for use as a system for short-range communications.

As is apparent from the above, the surface emitting laser element holding great promise as a light source for optical communications has a structural characteristic in that it includes a cavity and an active layer sandwiched by two reflecting mirror films with high reflectivities and in that a portion of the element forms a current confinement region (see, for example, Japanese Unexamined Patent Publications Nos. 2004-055688, 2003-188475, and 2003-086896).

In general, a reflecting mirror film used for a surface emitting laser element is a reflecting mirror of a multilayer film formed by epitaxial growth. The multilayer-film reflecting mirror is formed by alternately stacking two types of thin films made of different materials with different refractive indices, and the formed mirror can provide a reflectivity as high as 99.9% or more. As the material for the reflecting mirror film, a multilayer film of semiconductor is typically employed because this film has a high uniformity and can be formed simultaneously with formation of an active layer and the like during crystal growth. Other than this film, a dielectric multilayer film or the like is employed as the reflecting mirror film.

Current confinement regions for confining current injected into an active layer are classified into two broad categories: a proton implantation type in which protons are implanted into a cavity to form an insulating region and the formed region defines a current injection region; and a selective oxidation type in which an insulating oxide film of high resistance is formed around an active layer and the formed film defines a current injection region. The previous mainstream was the former, that is, the proton implantation type, but the recent mainstream has been shifting to the latter, that is, the selective oxidation type because of ease of its fabrication process, its high reproducibility, and other advantages.

Hereinafter, a selective oxidation type surface emitting laser element according to a first conventional example will be described with reference to FIG. 10. Referring to FIG. 10, the selective oxidation type surface emitting laser element according to the first conventional example includes: an n-type lower reflecting mirror film 201; a lower spacer layer 202; a quantum well layer 203; an upper spacer layer 204; a semiconductor layer (current confinement layer) 205; a p-type upper reflecting mirror film 206; and a p-type contact layer 207. The surface emitting laser element is formed by sequentially stacking, by a metal organic vapor phase epitaxy (MOVPE) method or the like, the listed components in this order on the principal surface of a substrate 200 made of gallium arsenide (GaAs). These stacked components are etched to form a columnar mesa structure (convex in cross section). The semiconductor layer 205 formed above the quantum well layer 203 contains Al, that is, this layer is made of, for example, aluminum arsenide (AlAs) or aluminum gallium arsenide (AlGaAs). Subsequently to the etching, the semiconductor layer 205 is thermally oxidized at about 400° C. This thermal oxidation selectively forms an oxidized insulating region 205b at an end of the semiconductor layer 205 containing Al, and thus a current confinement region 205a is formed in a center portion of the semiconductor layer 205. As shown above, since the current confinement region 205a defines a current injection region and concurrently a refractive index-guided structure can be constructed in the laser element, a strong optical-confinement effect can be provided. As a result of this, excellent properties such as low threshold current and high speed response can be obtained. Subsequently to the thermal oxidation, the mesa structure is covered with a passivation film 208 of silicon dioxide (SiO₂) or the like, and then a contact electrode 211 in contact with the contact layer 207 is formed over the surfaces of and around the mesa structure.

In order to use a surface emitting laser element for a light source for data communications, it is important for the element to have a structure capable of operating at high speed in a high frequency range. In order for the surface emitting laser element to accomplish a high-speed operation above 10 Gbit/s in the future, it is especially important to reduce the parasitic capacitance of the element.

A structural approach of the surface emitting laser element currently used in general is to employ the structure as shown in FIG. 10 in which the mesa structure is covered with an inorganic insulating film such as silicon dioxide.

However, the inorganic insulating film has a comparatively high relative permittivity. For example, SiO₂ has a relative permittivity of about four. Further, there is a limit (an upper limit) on the maximum formable thickness thereof, which causes the problem of an increase in the parasitic capacitance of the surface emitting laser element.

As one of solutions to this problem, the structure shown in FIG. 11 as a second conventional example is proposed in which a space surrounding the mesa structure is filled with a polyimide resin layer 215 (see, for example, IEEE PHOTONICS TECHNOLOGY LETTERS, Vol. 16, No. 4, April 2004, pp. 969 to 971).

However, when the technique in which the mesa structure is buried in the polyimide resin layer 215 is employed like the second conventional example shown in FIG. 11, the resin layer 215 significantly shrinks in volume by a thermal treatment performed to cure the polyimide resin layer 215. Shrinkage of the polyimide resin layer 215 generates a gap between the polyimide resin layer 215 and the mesa structure, which will cause a trouble of a decrease in the reliability and reproducibility of the element. Moreover, shrinkage of the thickness of the polyimide resin layer 215 makes it difficult to bury the mesa structure flat and uniformly. As a result of this, a level difference occurs at an upper edge of the polyimide resin layer 215 closer to the mesa structure, which may break the contact electrode 211.

Furthermore, if even part of the polyimide resin layer 215 is brought into contact with the semiconductor surface or exposed from the surface of the element, alteration of the polyimide resin layer 215 such as oxidation arises in a fabrication process of the element. As a consequence, the altered polyimide resin layer 215 chemically reacts with the semiconductor material. In addition, in the mesa structure having a certain side shape, an ununiform stress is applied to the polyimide resin layer 215, so that the gap mentioned above is more likely to be generated therebetween. These troubles cause a problem of degradation of reliability of the surface emitting laser element.

### SUMMARY OF THE INVENTION

An object of the present invention is to solve the conventional problems mentioned above and to provide a surface emitting laser element capable of highly reliable high-speed modulation.

To attain the above object, the present invention has the structure in which an insulating film covers a resin layer which fills a space surrounding a mesa structure in a semiconductor light-emitting element.

To be more specific, a semiconductor light-emitting element according to the present invention is characterized by including: a mesa structure of semiconductor formed to have a convex cross section; a first insulating film formed on a side surface of the mesa structure; a resin layer formed on the first insulating film to fill a space surrounding the mesa structure; a second insulating film covering the resin layer; and an electrode formed on the second insulating film to come into contact with part of the top surface of the mesa structure.

With the semiconductor light-emitting element of the present invention, the resin layer is prevented from coming into direct contact with the mesa structure and from being directly subjected to various atmospheres during fabrication processes, so that alteration of the resin layer can be avoided. This eliminates creation of a gap between the resin layer and the mesa structure to planarize the surrounding portion of the mesa structure by the resin layer. Therefore, a break in the electrode in contact with the top surface of the mesa structure is difficult to cause, and thereby a semiconductor light-emitting element with high reliability can be provided. That is to say, a surface emitting semiconductor laser element can be fabricated which has high reliability and excellent controllability of transverse mode and which can be modulated at high speed.

Preferably, in the semiconductor light-emitting element of the present invention, the resin layer is covered continuously with the first and second insulating films. With this element, degradation and alteration of the resin layer in fabrication steps can be prevented more reliably.

Preferably, in the semiconductor light-emitting element of the present invention, the resin layer has a relative permittivity of three or smaller. With this element, the parasitic capacitance associated with the contact portion of the resin layer with the electrode is decreased, which provides good high frequency characteristics.

Preferably, in the above case, the resin layer is made of benzocyclobutene (BCB) resin. Since BCB resin has a smaller relative permittivity and shrinks in volume less than polyimide resin, the mesa structure can be buried flat in the BCB resin with no gap created.

Preferably, in the semiconductor light-emitting element of the present invention, the first insulating film is formed to come into contact with the side surface of the mesa structure of the semiconductor and its surrounding portion, and the resin layer, the first insulating film, and the second insulating film are in contact with each other. With this element, alteration or the like of the resin layer is more difficult to cause, which provides a more stable resin layer.

Preferably, in the above case, at least part of the top surface of the resin layer is higher than the top surface of the mesa structure. With this element, the top surface of the mesa structure is lower than the top surface of the resin layer, and in addition, than the top surface of the second insulating film located on the resin layer. Therefore, jig or the like is unlikely to touch the top surface of the mesa structure in fabrication steps, so that the mesa structure can be protected from mechanical impact.

Preferably, in the semiconductor light-emitting element of the present invention, the mesa structure has a current confinement region formed selectively in a portion thereof. With this element, a current can be effectively injected into a desired portion of the mesa structure, so that a loss of the injected current can be reduced.

Preferably, in the above case, the current confinement region is formed so that the region is fully surrounded with an oxidized insulating region made by selective oxidation.

Preferably, in the above case, the current confinement region is formed so that the region is fully surrounded with an insulating region made by selective implantation of protons.

Preferably, in the case where the semiconductor light-emitting element of the present invention includes the current confinement region, the mesa structure has: lower and upper reflecting mirror films formed in lower and upper portions of the mesa structure, respectively; and an active layer formed between the lower and upper reflecting mirror films and in parallel with the top surface of the mesa structure. With this element, the lower and upper reflecting mirror films constitute a laser cavity. Therefore, a surface emitting semiconductor laser element can be provided which emits light of a predetermined wavelength perpendicularly to the principal surface of the active layer.

Preferably, in the above case, the lower and upper reflecting mirror films include semiconductor multilayer films, respectively. With this element, the reflecting mirror film with high reflectivity can be provided. Therefore, a high-power semiconductor laser element with high efficiency can be provided.

Preferably, in the case where the semiconductor light-emitting element of the present invention includes the active layer, the side surface of a portion of the mesa structure at which the active layer is located has an inclined angle of 40° or smaller with respect to a principal surface of the active layer. With this element, heat generated in the active layer can be efficiently dissipated downwardly from the mesa structure, and a uniform stress can be applied to the resin layer in contact with the first insulating film formed on the side surface of the mesa structure. This makes it difficult to cause a gap between the resin layer and the mesa structure.

Preferably, in the semiconductor light-emitting element of the present invention, the first and second insulating films are made of silicon oxide, silicon nitride, silicon oxynitride, niobium oxide, zirconium oxide, or tantalum oxide.

A method for fabricating a semiconductor light-emitting element according to the present invention is characterized by including the steps of: forming a semiconductor multilayer film on a substrate; selectively etching the semiconductor multilayer film to form the semiconductor multilayer film into a mesa structure with a convex cross section; forming a first insulating film on a side surface of the mesa structure and its surrounding portion; forming a resin layer on the first insulating film to fill a space surrounding the mesa structure; forming a second insulating film to cover the top of the resin layer and the perimeter of the top surface of the mesa structure; and forming an electrode on the second insulating film to come into contact with part of the top surface of the mesa structure.

With the method for fabricating a semiconductor light-emitting element according to the present invention, the semiconductor light-emitting element of the present invention can be fabricated reliably.

Preferably, in the method for fabricating a semiconductor light-emitting element according to the present invention, in the step of forming a resin layer, a coating method is carried out at least twice to apply the resin layer, and after every coating, the applied resin layer is cured. With this method, in filling a space surrounding the mesa structure with the resin layer, a flatter filling can be made.

Preferably, in the method for fabricating a semiconductor light-emitting element according to the present invention, a photosensitive resin material is used for at least part of the resin layer. With this method, a lithography method can change the thickness of the resin layer selectively. Therefore, various filling shapes can be employed.

Preferably, in the method for fabricating a semiconductor light-emitting element according to the present invention, the step of forming a resin layer includes: the substep of selectively light-exposing the photosensitive resin material; and the substep of developing the light-exposed resin material.

Preferably, in the method for fabricating a semiconductor light-emitting element according to the present invention, the resin layer is covered continuously with the first and second insulating films. With this method, in the step of forming a resin layer, degradation and alteration of the resin layer can be prevented more reliably.

### BRIEF DESCRIPTION OF THE DRAWINGS

FIGS. 1A and 1B show a surface emitting semiconductor laser element according to a first embodiment of the present invention. FIG. 1A is a plan view thereof, and FIG. 1B is a sectional view thereof taken along the line Ib-Ib of FIG. 1A.

FIGS. 2A and 2B show a close-to-actual surface emitting semiconductor laser element according to the first embodiment of the present invention. FIG. 2A is a sectional view thereof, and FIG. 2B is a microscope photograph of the cross section thereof.

FIGS. 3A and 3B show the performance characteristics of the surface emitting semiconductor laser element according to the first embodiment of the present invention. FIG. 3A is a graph showing the light output-current characteristic thereof, and FIG. 3B is a graph showing the far field pattern thereof.

FIGS. 4A to 4C are sectional views showing a method for fabricating a surface emitting semiconductor laser element according to the first embodiment of the present invention in the order of its fabrication process steps.

FIGS. 5A to 5C are sectional views showing the method for fabricating a surface emitting semiconductor laser element according to the first embodiment of the present invention in the order of its fabrication process steps.

FIGS. 6A to 6C are sectional views showing the method for fabricating a surface emitting semiconductor laser element according to the first embodiment of the present invention in the order of its fabrication process steps.

FIGS. 7A to 7C are sectional views showing the method for fabricating a surface emitting semiconductor laser element according to the first embodiment of the present invention in the order of its fabrication process steps.

FIGS. 8A and 8B show a surface emitting semiconductor laser element according to one modification of the first embodiment of the present invention. FIG. 8A is a sectional view showing the state of the element in which an insulating region for current confinement is formed by proton implantation, and FIG. 8B is a sectional view of the completed element.

FIG. 9 is a sectional view showing a surface emitting semiconductor laser, element according to a second embodiment of the present invention.

FIG. 10 is a sectional view showing a surface emitting semiconductor laser element according to a first conventional example.

FIG. 11 is a sectional view showing a surface emitting semiconductor laser element according to a second conventional example.

### DETAILED DESCRIPTION OF THE PREFERRED EMBODIMENTS

### First Embodiment

A first embodiment of the present invention will be described with reference to the accompanying drawings.

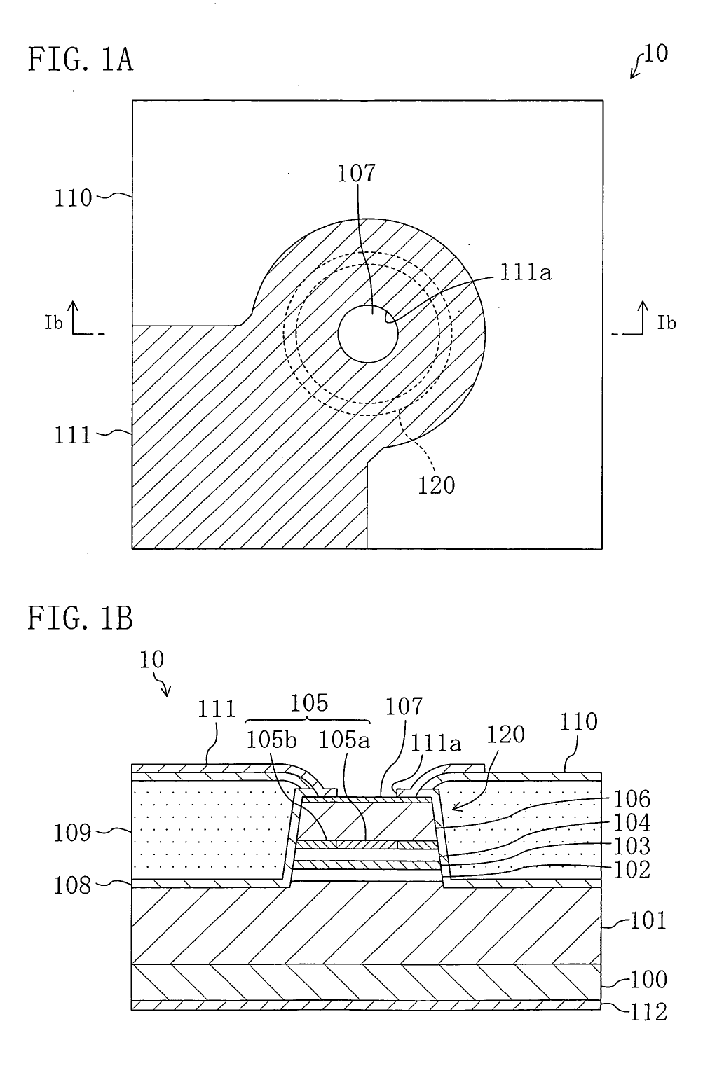

FIG. 1A shows the plan structure of a surface emitting semiconductor laser element according to the first embodiment of the present invention, and FIG. 1B shows a cross-sectional structure thereof taken along the line Ib-Ib in FIG. 1A.

Referring to FIGS. 1A and 1B, a surface emitting semiconductor laser element 10 according to the first embodiment includes: a lower reflecting mirror film 101 made of an n-type semiconductor multilayer film and having a multilayer thickness of 4.5 μm; a lower spacer layer 102 with a thickness of 87 nm; a quantum well layer 103 with a multilayer thickness of 40 nm; an upper spacer layer 104 with a thickness of 87 nm; a current confinement layer 105 with a thickness of 30 nm; an upper reflecting mirror film 106 made of a p-type semiconductor multilayer film and having a multilayer thickness of 3.0 μm; and a p-type contact layer 107 with a thickness of 5 nm. In the surface emitting semiconductor laser element 10, on the principal surface of a substrate 100 made of n-type GaAs and having a thickness of 300 μm, these films and layers are sequentially formed by epitaxial growth in the listed order from bottom to top.

The contact layer 107, the upper reflecting mirror film 106, the current confinement layer 105, the upper spacer layer 104, the quantum well layer 103, and the lower spacer layer 102 are etched in mesa shape to expose the lower reflecting mirror film 101, and thus the etched layers and films constitute a mesa structure 120.

On a side surface of the mesa structure 120 and a region of the lower reflecting mirror film 101 exposed beside the mesa structure 120, a first insulating film 108 is formed which is made of silicon dioxide (SiO₂) and has a thickness of 200 nm. In this element, the first insulating film 108 is also formed on the perimeter of the contact layer 107.

On the first insulating film 108, a resin layer 109 of benzocyclobutene (BCB) resin is formed to fill a space surrounding the mesa structure 120 with no gap created and to have a higher level than the top surface of the mesa structure 120.

On the resin layer 109, a second insulating film 110 of silicon dioxide having a thickness of 200 nm is formed to come into contact with the first insulating film 108 at the perimeter of the contact layer 107.

On the second insulating film 110, an upper contact electrode 111 is formed which comes into ohmic contact with the perimeter of the contact layer 107 and which has an electrode opening 111a exposing the contact layer 107. The upper contact electrode 111 is formed to cover the top end and its vicinity of the mesa structure 120 and one corner of the second insulating film 110.

On a surface of the substrate 100 opposite to the side of the lower reflecting mirror film 101 (the back surface of the substrate 100), a lower contact electrode 112 is formed which comes into ohmic contact with the substrate 100.

The lower reflecting mirror film 101 has a stacked structure formed by alternately stacking a first layer of n-type Al_{0.12}Ga_{0.88}As and a second layer of n-type Al_{0.90}Ga_{0.10}As. As an n-type impurity, silicon (Si) is doped. The thicknesses of the first and second layers are λ/4 n (where λ is the oscillation wavelength of the laser element, and n is the refractive index of a medium. Hereinafter, these letters indicate the respective parameters). Taking a combination of the first and second layers as one cycle, 34.5 cycles of the combinations are stacked to form the lower reflecting mirror film 101.

The quantum well layer 103 is formed by alternately stacking a well layer of a non-doped GaAs layer and a barrier layer of an Al_{0.30}Ga_{0.70}As layer. The number of well layers is three.

The lower spacer layer 102 and the upper spacer layer 104 are made of an Al_{0.30}Ga_{0.70}As layer. The quantum well layer 103, the lower spacer layer 102, and the upper spacer layer 104 constitute a quantum well active layer, and the total thickness of the quantum well active layer is λ/n.

The current confinement layer 105 is made of a p-type Al_{0.98}Ga_{0.02}As layer. This raises the Al content of a second layer of p-type Al_{0.90}Ga_{0.10}As forming the upper reflecting mirror film 106 that will be describer later, and the raised value is 0.98. In the first embodiment, the current confinement layer 105 is subjected to selective oxidation utilizing a characteristic in that the oxidation rate increases as the Al content thereof is high. Thereby, the center portion of the current confinement layer 105 is formed into a current confinement region 105a, and the end portion thereof is formed into an oxidized insulating region 105b.

The upper reflecting mirror film 106 has a stacked structure formed by alternately stacking a first layer of p-type Al_{0.12}Ga_{0.88}As and a second layer of p-type Al_{0.90}Ga_{0.10}As. As a p-type impurity, carbon (C) is doped. The thicknesses of the first and second layers are λ/4 n. Taking a combination of the first and second layers as one cycle, 22.5 cycles of the combinations are stacked to form the upper reflecting mirror film 106.

The contact layer 107 is made of a p-type GaAs layer. In order to decrease the contact resistance with the upper contact electrode 111, carbon as a p-type impurity is doped at a concentration of 1×10¹⁹ or higher.

Note that the materials for the first and second insulating films 108 and 110 are not limited to an inorganic insulating film made of silicon dioxide. Alternatively, silicon nitride (SiN), silicon oxynitride (SiON), niobium oxide (Nb₂O₅), zirconium oxide (ZrO₂), or tantalum oxide (Ta₂O₅) can be employed therefor.

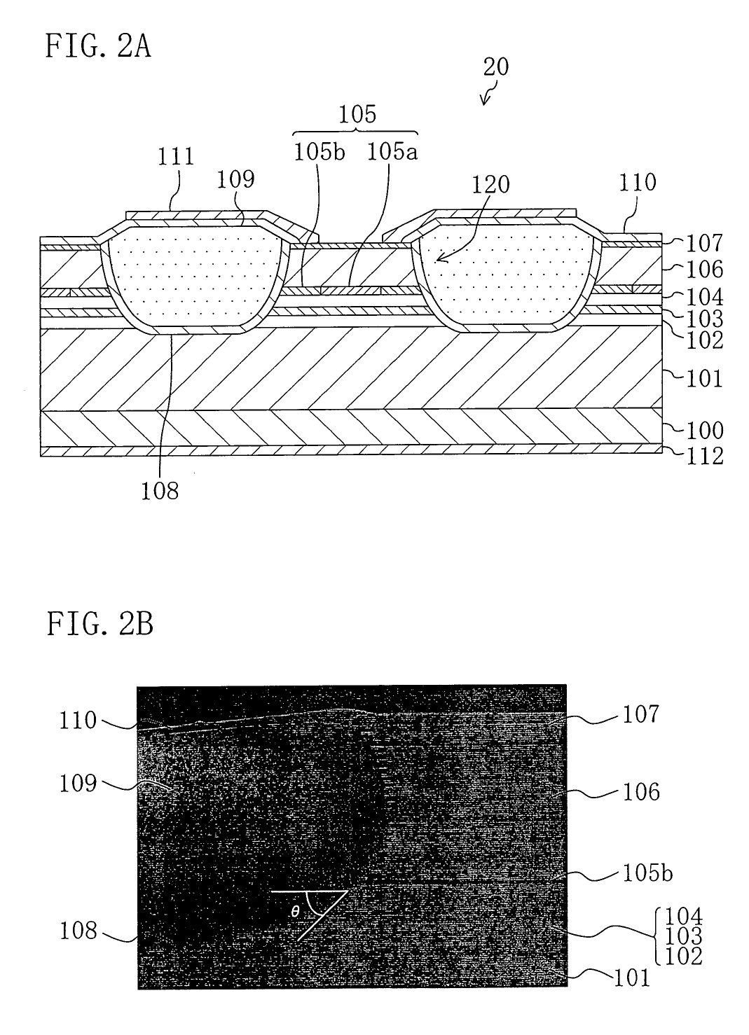

FIG. 2A shows a close-to-actual cross-sectional structure of the surface emitting laser element according to the first embodiment. Description of the components shown in FIG. 2A that are the same as those shown in FIG. 1B will be omitted by retaining the same reference numerals.

A surface emitting laser element 20 shown in FIG. 2A is constructed so that a side surface of the mesa structure 120 has a concave shape and the lower portion of the side surface is gently curved. FIG. 2B shows a photograph of a cross section of part of the mesa structure 120 observed with a scanning electron microscope. Note that the cross-sectional photograph shows the state of the element before a portion of the second protection layer 110 located on the mesa structure 120 is removed. As understood from FIG. 2B, the side surface of the mesa structure 120, the first insulating film 108, the resin layer 109, and the second insulating film 110 are in full contact with each other, so that oxidation or other alteration of the resin layer 109 will not occur in various processes. This prevents a gap from being created between the resin layer 109 and the mesa structure 120, so that a highly reliable surface emitting laser element can be provided.

Moreover, as shown in the photograph in FIG. 2B, the side surface of a portion of the mesa structure 120 at which the quantum well layer (active layer) 103 is located has a gently inclined angle. Thus, the lower portion of the mesa structure 120 has a contact area with the lower reflecting mirror film 101 larger than that of the case where the inclined angle θ of the side surface is large, specifically, close to 90°. Therefore, when a current injected from the upper contact electrode 111 generates laser light in the quantum well layer 103, a resultant heat can be dissipated efficiently into the lower reflecting mirror film 101 and the substrate 100. As a result, a surface emitting laser element with excellent temperature characteristics can be fabricated. In this structure, the side surface of a portion of the mesa structure 120 at which the quantum well layer 103 is located preferably has an inclined angle θ of 40° or smaller with respect to the in-plane orientation of the quantum well layer 103.

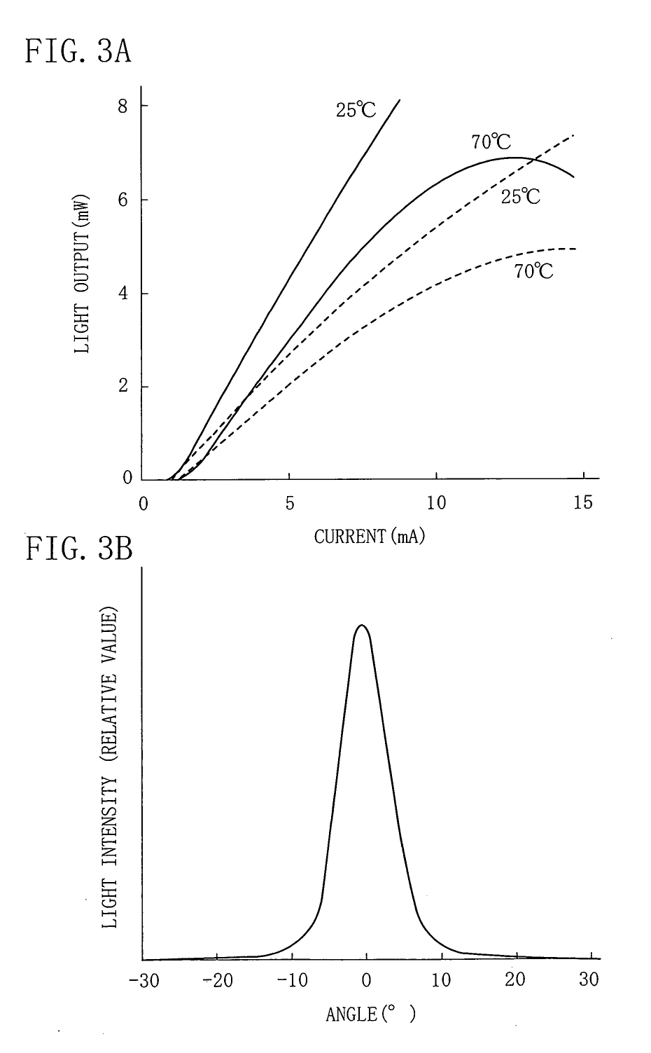

FIG. 3A shows the light output-current characteristic of the surface emitting semiconductor laser element according to the first embodiment. In this figure, the solid line shows the output characteristic of the laser element according to the present invention, while the broken line shows the output characteristic of the laser element according to the conventional example. From FIG. 3A, it is found that because of suppression of heat saturation, the laser element of the present invention provides high light output even at high temperatures.

FIG. 3B is a graph showing the far field pattern of the surface emitting semiconductor laser element according to the first embodiment. From FIG. 3B, it is found that the laser element according to the first embodiment oscillates in a single transverse mode. Therefore, the mesa structure 120 is buried in the resin layer 109 having a relatively low refractive index to construct refractive index-guided structure, whereby a laser element with a stable transverse mode can be provided.

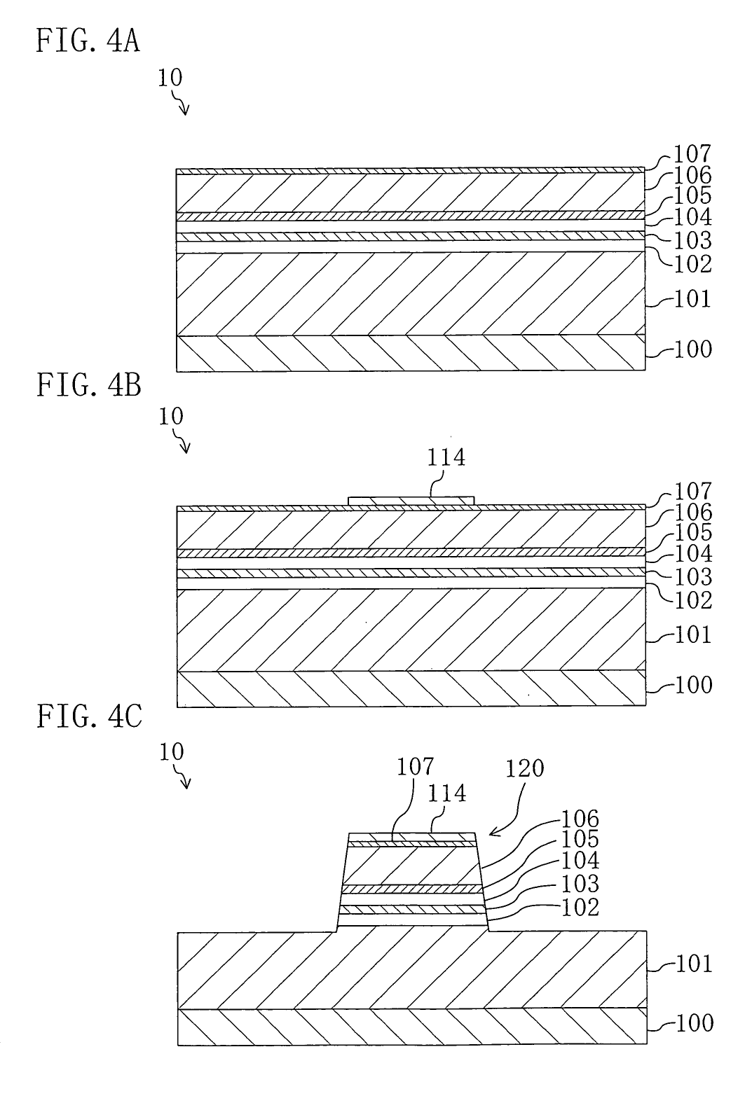

Hereinafter, a fabrication method of the surface emitting semiconductor laser element with the structure shown above will be described with reference to FIGS. 4 to 7. The components of FIGS. 4 to 7 that are the same as those shown in FIG. 1 retain the same reference numerals.

Referring to FIG. 4A, on the principal surface of the substrate 100 made of n-type GaAs, the n-type lower reflecting mirror film 101, the lower spacer layer 102, the quantum well layer 103, the upper spacer layer 104, the current confinement layer 105, the p-type upper reflecting mirror film 106, and the p-type contact layer 107 are sequentially formed by crystal growth using an MOVPE method or the like.

Next, by a chemical vapor deposition (CVD) method or a sputtering method, a silicon oxide film is deposited on the entire surface of the contact layer 107. Thereafter, as shown in FIG. 4B, a mask pattern 114 of silicon oxide covering a portion of the contact layer 107 located in a formation region of a mesa structure is formed by a lithography method and a dry etching method with an etching gas mainly containing fluorocarbon.

Subsequently, as show in FIG. 4C, using the mask pattern 114 as an etching mask, the contact layer 107, the upper reflecting mirror film 106, the current confinement layer 105, the upper spacer layer 104, the quantum well layer 103, the lower spacer layer 102, and the upper portion of the lower reflecting mirror film 101 are etched by a reactive ion etching (RIE) method with an etching gas containing chlorine such as chlorine (Cl₂), silicon tetrachloride (SiCl₄), or boron trichloride (BCl₃). Thus, the mesa structure 120 is formed. An object of the fabrication step of the mesa structure 120 is to expose the current confinement layer 105 from the side surface of the mesa structure 120, so that the lower reflecting mirror film 101 does not necessarily have to be exposed.

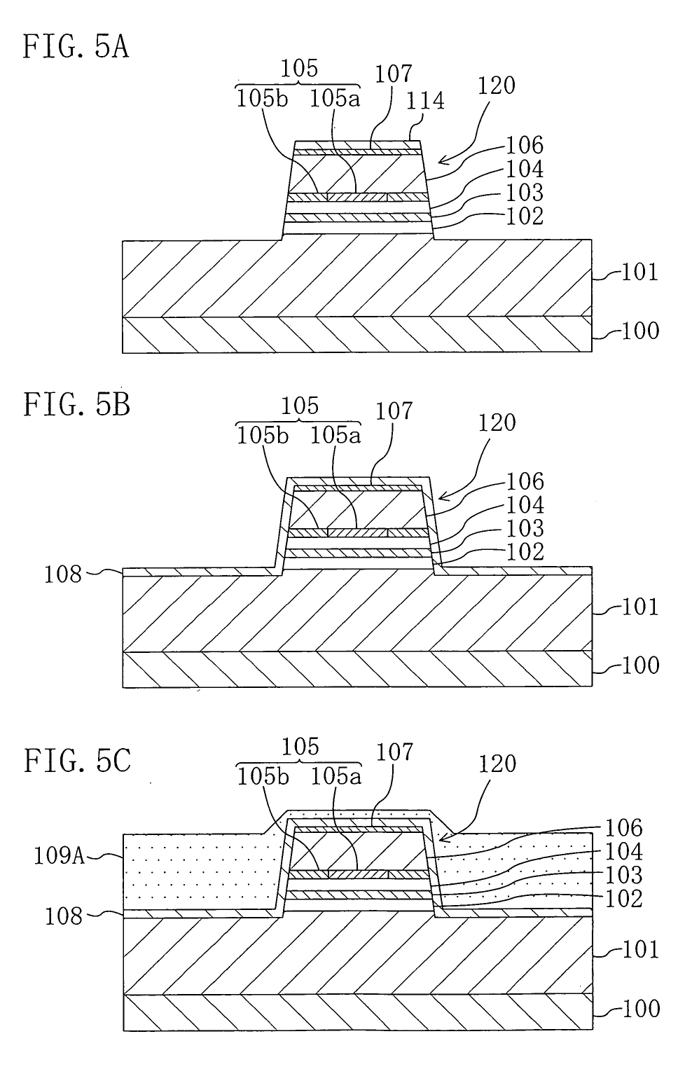

As shown in FIG. 5A, the formed mesa structure 120 is subjected to a hydrogen atmosphere at about 400° C. for about 15 minutes to oxidize the mesa structure 120 from outside. As described previously, the oxidation rate during this oxidation depends on the Al content of each semiconductor layer, that is, the oxidation rate increases as the Al content is high. In this structure, of the contact layer 107, the upper reflecting mirror film 106, the current confinement layer 105, the upper spacer layer 104, the quantum well layer 103, the lower spacer layer 102, and the lower reflecting mirror film 101, the current confinement layer 105 is allowed to have a higher Al content than the other films and layers to oxidize the current confinement layer 105 at a higher rate than the others. Thereby, the center portion of the mesa structure 120 is formed into the current confinement region 105a, and the end portion thereof is formed into the oxidized insulating region 105b with a high resistance.

Next, as shown in FIG. 5B, by a CVD method or a sputtering method, the first insulating film 108 of silicon dioxide is deposited on top and side surfaces of the mesa structure 120 and a portion of the lower reflecting mirror film 101 exposed beside the mesa structure 120.

Subsequently, as shown in FIG. 5C, onto the deposited first interlayer insulating film 108, a first resin layer 109A made of BCB is applied to eliminate the level difference due to the presence of the mesa structure 120 to planarize the entire top surface. Then, the applied first resin layer 109A is heated in a nitrogen atmosphere (at atmospheric pressure) at about 210° C. for about 40 minutes, thereby curing the first resin layer 109A.

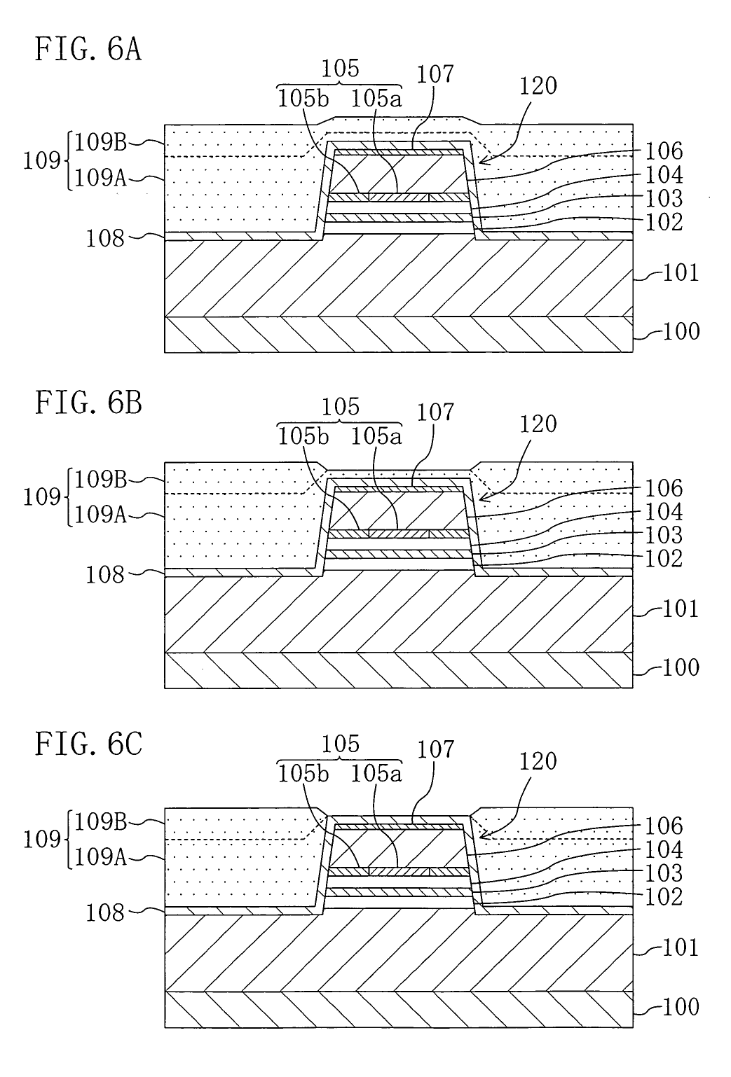

As shown in FIG. 6A, a second resin layer 109B made of BCB is applied again on the cured first resin layer 109A. The two-time application lessens the bump shape of the first resin layer 109A reflected from the convex mesa structure 120. In this process, since the second resin layer 109B before cure is negatively photosensitive, a lithography method can be employed for this layer like a typical photoresist material.

Therefore, as shown in FIG. 6B, a portion of the second resin layer 109B other than the portion thereof located on top of the mesa structure 120 is selectively light-exposed and then developed to remove the second resin layer 109B before cure. Thereby, in a portion of the resin layer 109 above the top of the mesa structure 120, the first resin layer 109A of is exposed. As a result of this, a portion of the resin layer 109 around the mesa structure 120 becomes higher than the top of the mesa structure 120. That is to say, the top surface of the mesa structure 120 is lower than the top surface of the surrounding resin layer 109, so that the surrounding resin layer 109 protects the top portion of the mesa structure 120 from mechanical contact. Moreover, the top surface of the resin layer 109 higher than the top surface of the mesa structure 120 can prevent a break in the upper contact electrode III that will be formed in a later step.

Subsequently, as shown in FIG. 6C, in order to expose a portion of the first insulating film 108 located on top of the mesa structure 120, part of the resin layer 109 is etched by a dry etching method. As an etching gas, use can be made of a mix gas of carbon tetrafluoride (CF₄) and oxygen (O₂). During this etching, the first insulating film 108 formed on the top surface of the mesa structure 120 is used as a layer for protecting the mesa structure 120. Thereafter, thermal treatment is performed in a nitrogen atmosphere (at atmospheric pressure) at about 320° C. for about 60 minutes, thereby curing the second resin layer 109B.

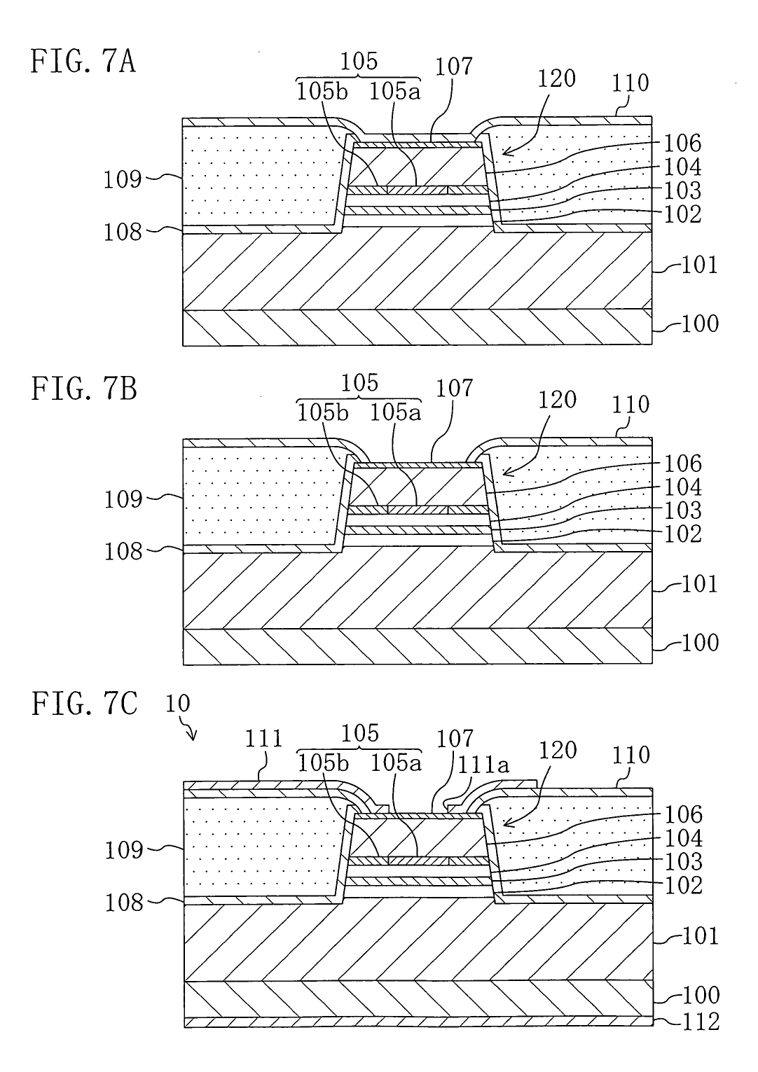

As shown in FIG. 7A, an exposed portion of the first insulating film 108 of silicon dioxide located on top of the mesa structure 120 is removed by wet etching with an etchant mainly containing hydrofluoric acid. Then, by a CVD method or a sputtering method, the second insulating film 110 of silicon dioxide is formed to cover the top surfaces of the resin layer 109 and the mesa structure 120 (the contact layer 107).

Next, as shown in FIG. 7B, a portion of the second insulating film 110 located on top of the mesa structure 120 is removed by wet etching with an etchant mainly containing hydrofluoric acid. Thereby, the second insulating film 110 is formed with a contact window for bringing the contact layer 107 into contact with the upper contact electrode 111 that will be formed later.

By a lithography method, on the second insulating film 110 and the contact layer 107, a photoresist pattern (not shown) is formed which has an opening pattern corresponding to an electrode pattern for forming the upper contact electrode 111. Subsequently, on the formed photoresist pattern, a multilayer metal film made of metal capable of ohmic contact with the p-type contact layer 107, such as a multilayer metal film made by stacking titanium (Ti)/platinum (Pt)/gold (Au) from bottom to top, is formed by a vapor deposition method or the like. Thereafter, the photoresist pattern is removed together with the multilayer metal film deposited on the photoresist pattern, that is, by a so-called liftoff method. Thus, as shown in FIGS. 7C and 1A, the upper contact electrode 111 is formed which has, on top of the mesa structure 120, the electrode opening 111a for emitting laser light.

Subsequently, the back surface of the substrate 100 opposite to the side of the lower reflecting mirror film 101 is polished or etched to thin the substrate to have a thickness of about 150 μm. Then, on the back surface of the thinned substrate, by a vapor deposition method or the like, the lower contact electrode is formed which is made of metal capable of ohmic contact with the n-type substrate 100, such as an alloy of gold (Au), germanium (Ge), and nickel (Ni) alloyed in this order from the substrate. Thermal treatment is performed in a nitrogen atmosphere at about 400° C. for 10 minutes to alloy the upper contact electrode 111 with the contact layer 107, and the lower contact electrode 112 with the substrate 100.

With the fabrication method described above, the surface emitting laser element according to the first embodiment can be provided.

### Modification of First Embodiment

One modification of the first embodiment of the present invention will be described below with reference to the accompanying drawings.

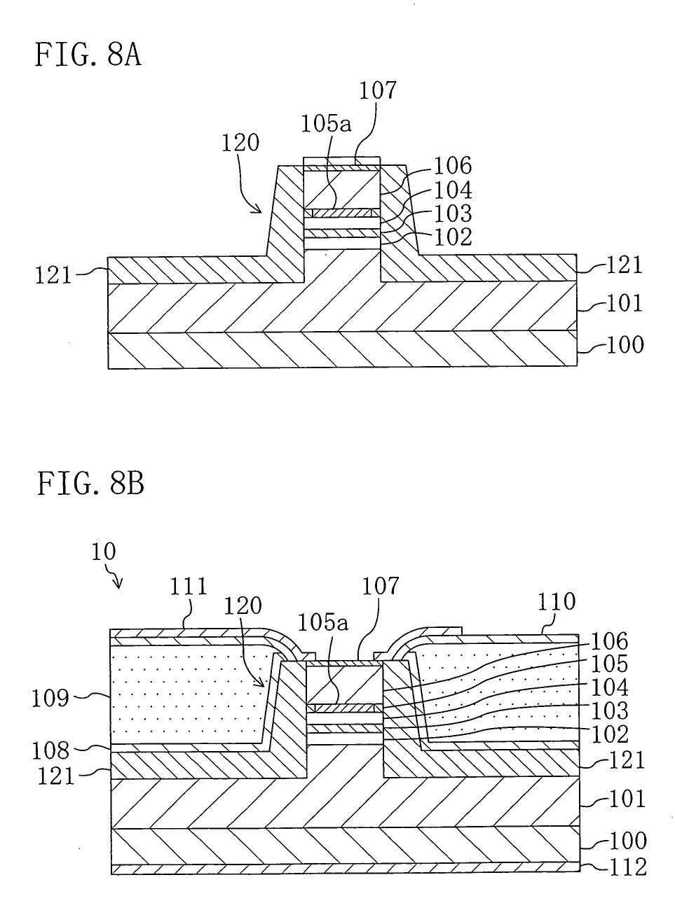

FIGS. 8A and 8B show a surface emitting semiconductor laser element according to one modification of the first embodiment of the present invention. FIG. 8A shows a cross-sectional structure thereof after protons are implanted into a side portion of a mesa structure and its surrounding region, and FIG. 8B shows a cross-sectional structure thereof after a space surrounding the mesa structure is filled with a resin layer and electrodes are formed. In FIGS. 8A and 8B, description of the components shown in these figures that are the same as those shown in FIG. 1B will be omitted by retaining the same reference numerals.

FIG. 8A shows a cross-sectional structure of the element after completion of the following procedure: the mesa structure 120 is formed by an RIE etching, and then into the formed mesa structure 120 and a portion of the lower reflecting mirror film 101 exposed around the mesa structure 120, protons are implanted at an acceleration voltage of about 300 to 400 keV. As shown in FIG. 8A, the side portion of the mesa structure 120 and the region surrounding the mesa structure 120 are formed with an insulating region 121 made by implanting protons. Thereby, not only the current confinement region 105a is formed in a side portion of the current confinement layer 105, but also a current injected into the mesa structure 120 is confined also in regions of the mesa structure 120 above and below the current confinement region 105a.

### Second Embodiment

A second embodiment of the present invention will be described below with reference to the accompanying drawings.

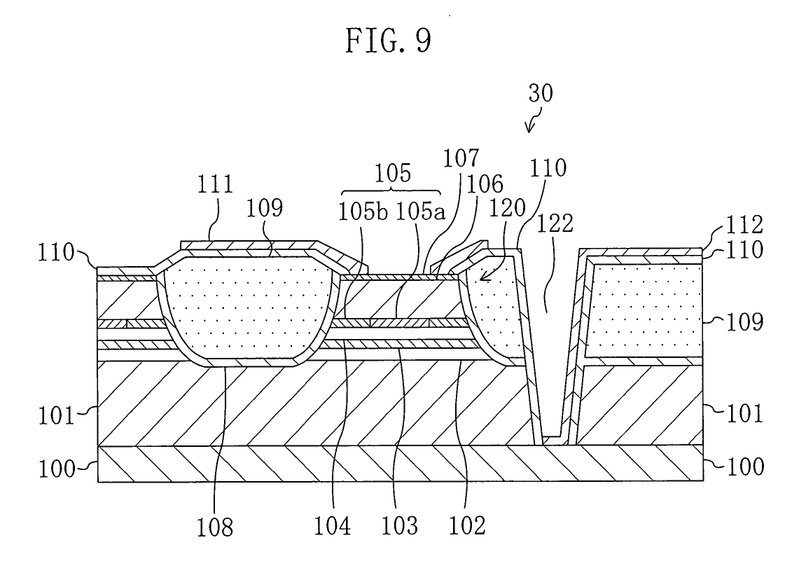

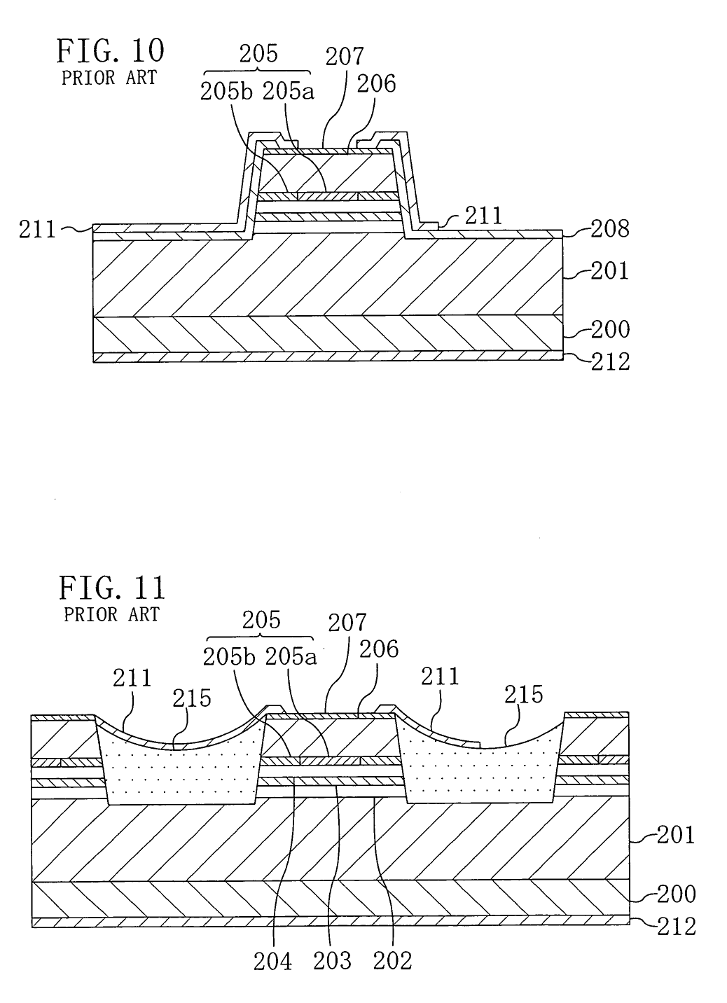

FIG. 9 shows a cross-sectional structure of a surface emitting semiconductor laser element according to the second embodiment of the present invention. Description of the components shown in FIG. 9 that are the same as those shown in FIG. 1B will be omitted by retaining the same reference numerals.

Referring to FIG. 9, in a surface emitting semiconductor laser element 30 according to the second embodiment, a contact hole 122 exposing the principal surface of the substrate 100 is formed through the resin layer 109 filling the space surrounding the mesa structure 120 and through the underlying lower reflecting mirror film 101.

On a side surface of the contact hole 122, the second insulating film 110 is formed to expose the substrate 100 at the bottom of the hole.

The contact hole 122 is formed with the lower contact electrode 112 with the second insulating film 110 interposed therebetween. At the bottom surface of the contact hole 122, a lower end of the lower contact electrode 112 comes into ohmic contact with the substrate 100, and an upper end thereof reaches the top surface of the resin layer 109.

Thus, in the second embodiment, the contact hole 122 reaching the substrate 100 is formed beside the mesa structure 120, and the lower contact electrode 112 is formed on the upper side of the element. This forms the structure of the element in which the lower contact electrode 112 and the upper contact electrode 111 do not interpose the substrate 100, so that the parasitic capacitance of the surface emitting semiconductor laser element 30 is further reduced.

Formation of the contact hole 122 creates irregularities on the surface of the laser element 30. However, since the resin layer 109 can be formed to have any thickness, the top surfaces of the upper contact electrode 111 and the lower contact electrode 112 which are located above the resin layer 109 can be formed flat.

In the first and second embodiments, description has been made of the case where the mesa structure 120 and the electrode opening 111a are circular. Alternatively, they can also be formed in any shape other than circular shape. Also in this case, the effects of the present invention can be effectively exerted.

In the first and second embodiments, the n-type lower reflecting mirror film 101, the p-type upper reflecting mirror film, and the p-type contact layer 107 are sequentially formed on the substrate 100 of n-type GaAs, but the combination of components of the element is not limited to this. For example, a p-type lower reflecting mirror film, an n-type upper reflecting mirror film, and an n-type contact layer can be sequentially formed on a substrate of p-type GaAs.

In the first and second embodiments, BCB resin is employed for the resin layer 109. However, the material for this layer is not limited to BCB resin, and a resin material with low permittivity can be employed therefor. As the resin material with low permittivity (low dielectric constant), use can be made of, for example, polyarylene-based resin material, “SiLK” (trademark) manufactured by Dow Chemical Company, or “FLARE” (trademark) manufactured by Honeywell International Incorporated.

In the first and second embodiments, description has been made of the surface emitting semiconductor laser element with an oscillation wavelength of about 850 nm, but irrespective of the oscillation wavelength, the effects of the present invention can be exerted also by a surface emitting semiconductor laser element with any oscillation wavelength.

As described above, in the surface emitting semiconductor laser element according to the present invention, the resin layer is prevented from being oxidized or altered in the element formation steps. This eliminates creation of a gap between the resin layer and the mesa structure. Thus, a surface emitting semiconductor laser element can be fabricated which has high reliability and excellent controllability of transverse mode and which can be modulated at high speed, so that it is useful for a light source for optical communications requiring high speed modulation.

What is claimed is:

1. A semiconductor light-emitting element comprising:
a mesa structure of semiconductor formed to have a convex cross section;
a first insulating film formed on a side surface of the mesa structure;
a resin layer formed on the first insulating film to fill a space surrounding the mesa structure;
a second insulating film covering the resin layer; and
an electrode formed on the second insulating film to come into contact with part of the top surface of the mesa structure.

2. The element of claim 1,
wherein the resin layer is covered continuously with the first and second insulating films.

3. The element of claim 2,
wherein the resin layer has a relative permittivity of three or smaller.

4. The element of claim 3,
wherein the resin layer is made of benzocyclobutene resin.

5. The element of claim 1,
wherein the first insulating film is formed to come into contact with the side surface of the mesa structure of the semiconductor and its surrounding portion, and the resin layer, the first insulating film, and the second insulating film are in contact with each other.

6. The element of claim 5,
wherein at least part of the top surface of the resin layer is higher than the top surface of the mesa structure.

7. The element of claim 1,
wherein the mesa structure has a current confinement region formed selectively in a portion thereof.

8. The element of claim 7,
wherein the current confinement region is formed so that the region is fully surrounded with an oxidized insulating region made by selective oxidation.

9. The element of claim 7,
wherein the current confinement region is formed so that the region is fully surrounded with an insulating region made by selective implantation of protons.

10. The element of claim 7,
wherein the mesa structure has: lower and upper reflecting mirror films formed in lower and upper portions of the mesa structure, respectively; and an active layer formed between the lower and upper reflecting mirror films and in parallel with the top surface of the mesa structure.

11. The element of claim 10,
wherein the lower and upper reflecting mirror films include semiconductor multilayer films, respectively.

12. The element of claim 10,
wherein the side surface of a portion of the mesa structure at which the active layer is located has an inclined angle of 40° or smaller with respect to a principal surface of the active layer.

13. The element of claim 1,
wherein the first and second insulating films are made of silicon oxide, silicon nitride, silicon oxynitride, niobium oxide, zirconium oxide, or tantalum oxide.

14. A method for fabricating a semiconductor light-emitting element, comprising the steps of:
forming a semiconductor multilayer film on a substrate;
selectively etching the semiconductor multilayer film to form the semiconductor multilayer film into a mesa structure with a convex cross section;
forming a first insulating film on a side surface of the mesa structure and its surrounding portion;
forming a resin layer on the first insulating film to fill a space surrounding the mesa structure;
forming a second insulating film to cover the top of the resin layer and the perimeter of the top surface of the mesa structure; and
forming an electrode on the second insulating film to come into contact with part of the top surface of the mesa structure.

15. The method of claim 14,
wherein in the step of forming a resin layer, a coating method is carried out at least twice to apply the resin layer, and after every coating, the applied resin layer is cured.

16. The method of claim 14,
wherein a photosensitive resin material is used for at least part of the resin layer.

17. The method of claim 16,
wherein the step of forming a resin layer includes: the substep of selectively light-exposing the photosensitive resin material; and the substep of developing the light-exposed resin material.

18. The method of claim 14,
wherein the resin layer is covered continuously with the first and second insulating films.
